(19) United States
(12) Patent Application Publication
(10) Pub. No.: US 2016/0266496 A1
(43) Pub. Date: Sep. 15, 2016

(54) FABRICATION AND ENCAPSULATION OF MICRO-CIRCUITS ON DIAMOND AND USES THEREOF

(71) Applicant: UAB Research Foundation, Birmingham, AL (US)

(72) Inventors: Gopi Krishna Samudrala, Birmingham, AL (US); Yogesh K. Vohra, Hoover, AL (US); Samuel Moore, Birmingham, AL (US)

(21) Appl. No.: 15/067,091

(22) Filed: Mar. 10, 2016

Related U.S. Application Data
(60) Provisional application No. 62/131,238, filed on Mar. 10, 2015.

(51) Int. Cl. G03F 7/40; C23C 16/511; G03F 7/42; G03F 7/20; G03F 7/32

(52) U.S. Cl. CPC G03F 7/40; G03F 7/20; G03F 7/32; G03F 7/42; C23C 16/511

(57) ABSTRACT

In one aspect, the invention relates to methods to fabricate sensors on diamond anvils and the sensors prepared by the disclosed methods. This abstract is intended as a scanning tool for purposes of searching in the particular art and is not intended to be limiting of the present invention.

### CROSS-REFERENCE TO RELATED APPLICATIONS

This application claims the benefit of U.S. Provisional Application No. 62/131,238, filed on Mar. 10, 2015, which is incorporated herein fully by reference in its entirety.

### STATEMENT REGARDING FEDERALLY SPONSORED RESEARCH

This invention was made with government support under grant number IIP-1317210, awarded by the National Science Foundation Partnership for Innovation (NSF:PFI) program, and under grant number DE-NA0002014, awarded by the Department of Energy (DOE)-National Nuclear Security Administration. The government has certain rights in the invention.

### BACKGROUND

The static high pressure study on materials generally requires the use of single crystal diamonds in an opposed anvil configuration in diamond anvil cell devices. The high shear strength of diamond allows for the generation of ultra-high pressure conditions at the tip of these anvils and transparency of diamond to a variety of electromagnetic radiations allows for a number of spectroscopic and diffraction measurements to be performed on materials under extreme conditions. In high pressure research, studying the electrical and magnetic properties of materials is accomplished by placing electrical probes in the sample region. These probes are in the region where shearing stress exceeds 10 GPa (Hemley et al. (1997) X-ray Imaging of Stress and Strain of Diamond, Iron, and Tungsten at Megabar Pressures. Science 276: 1242-1245), and temperatures are very high or very low. Therefore, protecting the probes from these extreme conditions is very important to gain reliable and meaningful data.

Designer diamond anvils facilitate this by encapsulating electrical probes under chemical vapor deposition grown diamond. It has been shown that designer diamond anvils can be used to study materials at extreme conditions such as megabar pressures and very low temperatures (Velisavljevic et al. (2004) Electrical measurements on praseodymium metal to 179 GPa using designer diamond anvils. Appl. Phys. Lett. 84: 927-929; Jackson et al. (2005) High-pressure magnetic susceptibility experiments on the heavy lanthanides Gd, Tb, Dy, Ho, Er, and Tm. Phys. Review B 71; Samudrala et al. (2014) Structural and magnetic phase transitions in gadolinium under high pressures and low temperatures. High Press. Res. 34: 385-391; Samudrala et al. (2014) Magnetic ordering temperatures in rare earth metal dysprosium under ultrahigh pressures. High Press. Res. 34: 266-272). It has been shown previously that using a diamond anvil as a substrate, designer anvils can be produced by the use of lithography, laser pantography, and CVD growth techniques (Weir et al. (2000) Epitaxial diamond encapsulation of metal microprobes for high pressure experiments. Appl. Phys. Lett. 77: 3400-3402). These methods require the use of highly customized and expensive tools. Mask aligners need to be used for this method and physical masks tailored to each pattern to be drawn on diamond anvils need to be prepared and replaced after few uses.

Despite the variety of known uses of designer diamond anvils in extreme conditions including pressure, temperature, corrosion, and radiation, the manufacture of diamond anvils is impeded by the use of customized, expensive tools. Accordingly, there remains a need for methods of fabricating and encapsulating electrical and magnetic sensors in single crystal diamond, polycrystalline diamond, and diamond based composites.

### SUMMARY

In accordance with the purpose(s) of the invention, as embodied and broadly described herein, the invention, in one aspect, relates to methods to fabricate sensors on diamond anvils and the sensors prepared by the disclosed methods.

Disclosed are methods for creating a metal pattern on a surface of a diamond, the method comprising: (a) providing a diamond substrate having a surface; (b) depositing a uniform metal layer onto the surface; (c) applying a uniform polymer photoresist coating onto the metal layer; (d) exposing the substrate to light, wherein the light makes positive tone photoresist coating soluble in a developing solution, and wherein the light makes negative tone photoresist insoluble in a developing solution; (e) developing the photoresist coating after exposing it to light, wherein a pattern is created on the photoresist coating, thereby exposing any excess metal; (f) dissolving the excess metal; and (g) stripping the polymer resist coating, thereby creating the metal pattern on the surface of the diamond.

Also disclosed are methods for creating a metal pattern on a surface of a diamond, the method comprising: (a) providing a diamond substrate having a surface; (b) applying a uniform polymer photoresist coating onto the surface; (c) exposing the substrate to light, wherein the light makes the exposed photoresist insoluble in a developing solution; (d) immersing the substrate in a developing solution and creating a pattern on the polymer resist coating, thereby exposing a portion of the surface; (e) depositing a uniform metal layer onto the portion of the surface; and (f) stripping the polymer resist coating; thereby creating the metal pattern on the surface of the diamond.

Also disclosed are sensors prepared by the disclosed methods.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### BRIEF DESCRIPTION OF THE DRAWINGS

The accompanying figures, which are incorporated in and constitute a part of this specification, illustrate several aspects and together with the description serve to explain the principles of the invention.

FIGS. 1A-1C show schematic representations of the disclosed methods. FIG. 1A shows in the top row the steps involved in fabricating a designer diamond through the wet etch process, and in the bottom row shows the steps involved in fabricating designer diamond anvils through the lift-off process. FIG. 1B shows an alternative schematic representation of the steps involved in fabricating designer diamond anvils through the wet etch process. FIG. 1C shows an alternative schematic representation of the steps involved in fabricating a designer diamond through the lift-off process.

FIGS. 2A-2C show representative disclosed sensors fabricated on diamond anvils. FIG. 2A shows eight electrical probes lithographed onto diamond anvil. FIG. 2B shows CVD diamond grown on top of eight probe pattern. FIG. 2C shows a fully fabricated designer diamond anvil with a culet size of 370 microns with a probe circle diameter of 85 microns.

FIGS. 3A-3C show representative disclosed sensors fabricated on diamond anvils. FIG. 3A shows a Ca_{0.9}Pr_{0.1}Fe₂As₂ sample loaded in a diamond anvil cell along with steatite pressure medium, and ruby for pressure calibration. FIG. 3B shows electrical resistance data collected with a designer diamond anvil. The insert shows the method of determining the onset of superconductivity (Tc). FIG. 3C shows Tc as a function of pressure for Ca0.9Pr0.1Fe2As2.

FIGS. 4A-4D show representative images of the steps involved in the fabrication of two-stage diamond micro-anvils employed in high pressure studies. FIG. 4A shows a diamond with tungsten mask exposing only the central 50 μm region diamond substrate for diamond growth. FIG. 4B shows a scanning electron microscopy (SEM) image showing the side view of CVD grown micro-diamond anvil. FIG. 4C shows a close up SEM image of the diamond micro-anvil. FIG. 4D shows a high-resolution SEM image showing surface growth steps characteristic of homoepitaxial growth morphology of the diamond micro-anvil.

FIG. 5 shows representative Raman spectroscopic data from the second-stage diamond micro-anvil showing a predominant diamond peak at 1332 cm⁻¹ with only a week broad non-diamond component in the 1560 cm⁻¹ range. The inset shows an SEM image (top view) of the second-stage micro-anvil where the Raman data were collected from the central region.

FIG. 6 shows a two-stage diamond micro-anvil mounted in an opposed anvil configuration against a standard single-stage diamond anvil for high pressure experiments.

FIG. 7 shows the angle-dispersive X-ray diffraction pattern for the lutetium sample and copper pressure standard at a pressure of 86 GPa obtained with the diamond micro-anvil. The incident X-ray beam energy is 30.494 keV. The diffraction peaks from the lutetium sample are indexed to a dhcp structure, while the copper peaks marked by asterisk (*) are indexed to a face-centered cubic structure. The weak peaks marked by “g” are from the hcp phase of the iron gasket. The vertical bars represent the fitted peak positions for both the copper pressure standard and lutetium sample.

FIG. 8 shows the pressure distribution across the second-stage diamond micro-anvil grown by the CVD method. The entire pressure scan across 60 μm×60 μm was obtained in 5 min using a fast X-ray detector. The pressure values indicated are based on a copper pressure standard. The contours are drawn as a guide to the eye.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

Still other objects and advantages of the present disclosure will become readily apparent by those skilled in the art from the following detailed description, wherein it is shown and described only the preferred embodiments, simply by way of illustration of the best mode. As will be realized, the disclosure is capable of other and different embodiments, and its several details are capable of modifications in various obvious respects, without departing from the disclosure. Accordingly, the description is to be regarded as illustrative in nature and not as restrictive.

### DETAILED DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

Throughout this application, various publications are referenced. The disclosures of these publications in their entireties are hereby incorporated by reference into this application in order to more fully describe the state of the art to which this pertains. The references disclosed are also individually and specifically incorporated by reference herein for the material contained in them that is discussed in the sentence in which the reference is relied upon. Nothing herein is to be construed as an admission that the present invention is not entitled to antedate such publication by virtue of prior invention. Further, the dates of publication provided herein may be different from the actual publication dates, which can require independent confirmation.

As used herein, the terms “about,” “approximate,” and “at or about” mean that the amount or value in question can be the exact value designated or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

### A. Designer Diamond Anvils

In high pressure research, studying the electrical and magnetic properties of materials is accomplished by placing electrical probes in the sample region. To withstand the extreme conditions of the high-pressure research environment, these probes are then encapsulated under a chemical vapor deposited (CVD) diamond layer. The final product after polishing then is a diamond anvil which has micro probes embedded under CVD diamond with only the very edges of the probes exposed in the sample region. These “Designer Diamond Anvils” have been successfully employed in multiple experiments where properties of materials have been measured with unprecedented accuracy. This technique of fabricating and encapsulating electrical and magnetic sensors in single crystal diamond, polycrystalline diamond, and diamond based composites results in an advanced sensor platform for extreme environments of pressure, temperature, corrosion, and radiation.

Diamond single crystals, polycrystalline diamonds, and composite materials based on diamond can withstand extreme conditions of pressure, temperature, corrosion, and radiation. To study the properties of materials at extreme conditions, single crystal diamond anvils are used to generate ultrahigh pressures. To be able to accurately measure characteristics such as electrical conductivity and magnetic susceptibility under extreme conditions, it is necessary to have metallic probes that can withstand the high pressure—high temperature conditions of the experiments. In a typical high pressure research experiment, the dimensions of these probes are of the order of a few microns. Additionally, these probes need to be placed on the culets of diamond anvils precisely.

As mentioned earlier, several important studies have been carried out in high pressure research utilizing designer diamond anvils. The use of designer diamond anvils in diamond anvil cell allows for a metallic gasket to be used for sample containment and for precise four-probe electrical resistance measurements. This is particularly helpful in observing how superconductivity changes as a function of pressure in compounds such as 1-2-2 iron (Fe)-based materials AFe₂As₂ (122) [A=Ba, Sr, Ca, Eu]. High pressure superconductivity in a rare-earth-doped Ca_{0.86}Pr_{0.14}Fe₂As₂ single-crystalline sample has been studied up to 12 GPa and temperatures down to 11 K using the designer diamond anvil previously (Uhoya et al. (2014) High pressure effects on the superconductivity in rare-earth-doped CaFe₂As₂. High Press. Res. 34: 49-58). These superconducting compounds are of particular interest because under pressure, superconducting transition temperature (T_{c}) as high as ˜51 K at 1.9 GPa has been observed, presenting the highest T_{c} reported in the intermetallic class of 1-2-2 iron-based superconductors.

### B. Maskless Lithography

The use of maskless lithography allows the need for the use of multiple systems to draw electrical circuits on diamond anvils to be eliminated. The maskless lithography not only allows us to fabricate designer diamond anvils but also makes it possible to fabricate other diamond based sensors such as thermocouples that can function in extreme environments.

### C. Two-Stage Diamond Anvils

In various aspects, the present invention relates to methods for generating high pressures so that properties of materials can be investigated at those conditions is as described below. For example, two diamonds, i.e., two diamond anvils, can be arranged such that their culets are in alignment. When the culets are pressed together, per the relationship that pressure=force/area; a very high pressure is generated between the culets. A material of interest is placed between the culets and is studied utilizing various techniques such as x-ray diffraction to determine its structure, and the like.

In currently available methods, a foreign object is being placed in the central culet region of the diamond anvils. Invariably, the foreign objects move or are crushed under high pressures thus rendering the pressure generation process inconsistent. The present invention relates to improvements to using two diamond anvils using the disclosed methods such that the “second stage” diamond is a natural extension of the existing diamond. This improvement is achieved this by a combination of maskless lithography and chemical vapor deposition.

In various aspects, a diamond anvil can be been coated in tungsten by sputter deposition process. The diamond anvil is then coated in photoresist. Utilizing maskless lithography, the photoresist from a small region in the center of the culet can be been removed. The diamond anvil is placed in tungsten etchant. In essence, the method provides for the creation of a hole in the tungsten coating. Due to the use of the disclosed methods, in particular, the utilization of lithographic techniques, the reproducibility in this process is ensured. The diamond is then placed in a CVD chamber and diamond growth conducted by chemical vapor deposition process as described herein. The excess tungsten can then be removed by dissolution and a diamond anvil remains which has a small diamond growth in the center of the culet. The feasibility of generating high pressures beyond the capability of traditional anvils is described herein.

### D. Methods for Preparation of Sensors on Diamond Anvils

In various aspects, the present invention relates to methods for creating a metal pattern on a surface of a diamond, the method comprising: (a) providing a diamond substrate having a surface; (b) depositing a uniform metal layer onto the surface; (c) applying a uniform polymer photoresist coating onto the metal layer; (d) exposing the substrate to light, wherein the light makes positive tone photoresist coating soluble in a developing solution, and wherein the light makes negative tone photoresist insoluble in a developing solution; (e) developing the photoresist coating after exposing it to light, wherein a pattern is created on the photoresist coating, thereby exposing any excess metal; (f) dissolving the excess metal; and (g) stripping the polymer resist coating, thereby creating the metal pattern on the surface of the diamond.

In a further aspect, the substrate is a single crystal. In a yet further aspect, the single crystal is about one-third carat.

In a further aspect, depositing a uniform metal layer comprises sputter deposition.

In a further aspect, the metal layer comprises tungsten, iridium, molybdenum, or osmium, or combinations thereof. In a still further aspect the metal comprises tungsten. In a yet further aspect the metal comprises iridium. In an even further aspect the metal comprises molybdenum. In a still further aspect the metal comprises osmium.

In a further aspect, the metal layer has a thickness from about 0.1 microns to about 2 microns. In a still further aspect, the metal layer has a thickness from about 0.2 microns to about 2 microns. In a yet further aspect, the metal layer has a thickness from about 0.3 microns to about 2 microns. In an even further aspect, the metal layer has a thickness from about 0.4 microns to about 2 microns. In a still further aspect, the metal layer has a thickness from about 0.5 microns to about 2 microns. In a yet further aspect, the metal layer has a thickness from about 0.6 microns to about 2 microns. In an even further aspect, the metal layer has a thickness from about 0.7 microns to about 2 microns. In a still further aspect, the metal layer has a thickness from about 0.8 microns to about 2 microns. In a yet further aspect, the metal layer has a thickness from about 0.9 microns to about 2 microns. In an even further aspect, the metal layer has a thickness from about 1 micron to about 2 microns.

In a further aspect, the metal layer has a thickness from about 0.1 microns to about 1 micron. In a yet further aspect, the metal layer has a thickness from about 0.1 microns to about 0.9 microns. In an even further aspect, the metal layer has a thickness from about 0.1 microns to about 0.8 microns. In a still further aspect, the metal layer has a thickness from about 0.1 microns to about 0.7 microns. In a yet further aspect, the metal layer has a thickness from about 0.1 microns to about 0.6 microns. In an even further aspect, the metal layer has a thickness from about 0.1 microns to about 0.5 microns. In a still further aspect, the metal layer has a thickness from about 0.1 microns to about 0.4 microns. In a still further aspect, the metal layer has a thickness from about 0.1 microns to about 0.45 microns. In a yet further aspect, the metal layer has a thickness from about 0.1 microns to about 0.4 microns.

In a further aspect, the metal layer has a thickness from about 0.15 microns to about 1 micron. In a yet further aspect, the metal layer has a thickness from about 0.15 microns to about 0.9 microns. In an even further aspect, the metal layer has a thickness from about 0.15 microns to about 0.8 microns. In a still further aspect, the metal layer has a thickness from about 0.15 microns to about 0.7 microns. In a yet further aspect, the metal layer has a thickness from about 0.15 microns to about 0.6 microns. In an even further aspect, the metal layer has a thickness from about 0.15 microns to about 0.5 microns. In a still further aspect, the metal layer has a thickness from about 0.15 microns to about 0.45 microns. In a yet further aspect, the metal layer has a thickness from about 0.15 microns to about 0.4 microns.

In a further aspect, the metal layer has a thickness from about 0.2 microns to about 1 micron. In a yet further aspect, the metal layer has a thickness from about 0.2 microns to about 0.9 microns. In an even further aspect, the metal layer has a thickness from about 0.2 microns to about 0.8 microns. In a still further aspect, the metal layer has a thickness from about 0.2 microns to about 0.7 microns. In a yet further aspect, the metal layer has a thickness from about 0.2 microns to about 0.6 microns. In an even further aspect, the metal layer has a thickness from about 0.2 microns to about 0.5 microns. In a still further aspect, the metal layer has a thickness from about 0.2 microns to about 0.45 microns. In a yet further aspect, the metal layer has a thickness from about 0.2 microns to about 0.4 microns.

In a further aspect, the metal layer has a thickness from about 0.25 microns to about 1 micron. In a yet further aspect, the metal layer has a thickness from about 0.25 microns to about 0.9 microns. In an even further aspect, the metal layer has a thickness from about 0.25 microns to about 0.8 microns. In a still further aspect, the metal layer has a thickness from about 0.25 microns to about 0.7 microns. In a yet further aspect, the metal layer has a thickness from about 0.25 microns to about 0.6 microns. In an even further aspect, the metal layer has a thickness from about 0.25 microns to about 0.5 microns. In a still further aspect, the metal layer has a thickness from about 0.25 microns to about 0.45 microns. In a yet further aspect, the metal layer has a thickness from about 0.25 microns to about 0.4 microns.

In a further aspect, applying comprises a spin coater.

In a further aspect, the spin coater has an angular velocity of from about 1000 rpm to about 12000 rpm. In a yet further aspect, the spin coater has an angular velocity of from about 1000 rpm to about 11000 rpm. In an even further aspect, the spin coater has an angular velocity of from about 1000 rpm to about 10000 rpm. In a still further aspect, the spin coater has an angular velocity of from about 1000 rpm to about 9000 rpm. In a yet further aspect, the spin coater has an angular velocity of from about 1000 rpm to about 8000 rpm. In a still further aspect, the spin coater has an angular velocity of from about 1000 rpm to about 7000 rpm. In a still further aspect, the spin coater has an angular velocity of from about 1000 rpm to about 6000 rpm. In a still further aspect, the spin coater has an angular velocity of from about 1000 rpm to about 5000 rpm. In a still further aspect, the spin coater has an angular velocity of from about 1000 rpm to about 4000 rpm. In a still further aspect, the spin coater has an angular velocity of from about 1000 rpm to about 3000 rpm. In a still further aspect, the spin coater has an angular velocity of from about 1000 rpm to about 2000 rpm.

In a further aspect, the spin coater has an angular velocity of from about 2000 rpm to about 12000 rpm. In a yet further aspect, the spin coater has an angular velocity of from about 3000 rpm to about 12000 rpm. In an even further aspect, the spin coater has an angular velocity of from about 4000 rpm to about 12000 rpm. In a still further aspect, the spin coater has an angular velocity of from about 5000 rpm to about 12000 rpm. In a yet further aspect, the spin coater has an angular velocity of from about 6000 rpm to about 12000 rpm. In a still further aspect, the spin coater has an angular velocity of from about 7000 rpm to about 12000 rpm. In a still further aspect, the spin coater has an angular velocity of from about 8000 rpm to about 12000 rpm. In a still further aspect, the spin coater has an angular velocity of from about 9000 rpm to about 12000 rpm. In a still further aspect, the spin coater has an angular velocity of from about 9000 rpm to about 12000 rpm. In a still further aspect, the spin coater has an angular velocity of from about 10000 rpm to about 12000 rpm. In a still further aspect, the spin coater has an angular velocity of from about 11000 rpm to about 12000 rpm.

In a further aspect, the spin coater has an angular velocity of about 1000 rpm, about 1500 rpm, about 2000 rpm, about 2500 rpm, about 3000 rpm, about 3500 rpm, about 4000 rpm, about 4500 rpm, about 5000 rpm, about 5500 rpm, about 6000 rpm, about 6500 rpm, about 7000 rpm, about 7500 rpm, about 8000 rpm, about 8500 rpm, about 9000 rpm, about 9500 rpm, about 10000 rpm, about 10500 rpm, about 11000 rpm, about 11500 rpm, or about 12000 rpm.

In a further aspect, the polymer photoresist coating comprises 1-methoxy-2-propanol acetate, gamma butyrolactone, or combinations thereof. In a still further aspect, the polymer photoresist coating is a positive tone resist. In a yet further aspect, the polymer photoresist coating is a negative tone resist. Commercially available positive tone resists useful in the disclosed methods include, but are not limited to, materials such as AZ 1500 series photoresists and Shipley 1800 series photoresists. Commercially available negative tone resists useful in the disclosed methods include, but are not limited to, materials such as AZ nLof series photoresists and Microchem's SU-8 series photoresists. Commercially available materials for the lift-off process useful in the disclosed methods include, but are not limited to, materials Microchem's PMGI/LOR.

In a further aspect, exposing the photoresist to specific wavelengths of electromagnetic radiation comprises maskless lithography. In a still further aspect, photoresist exposing to these specific wavelengths of electromagnetic radiation comprises a digital micro mirror device. In a yet further aspect, the wavelength of the exposure light is in the range of from about 360 nm to about 450 nm. In an even further aspect, the wavelength of the exposure light is in the range of from about 436 nm. In a still further aspect, the wavelength of the exposure light is in the range of from about 365 nm. These wavelengths can be generated by lasers and polychromatic light sources such as light emitting diodes and mercury arc lamps.

In a further aspect, dissolving the excess metal comprises wet etching. In a still further aspect, wet etching comprises exposing the surface to an acidic etchant solution. In a yet further aspect, stripping comprises exposing the surface to a solvent.

In a further aspect, the method further comprises the step of encapsulating the surface with single crystal diamond. In a still further aspect, encapsulating comprises microwave plasma chemical vapor deposition. In a yet further aspect, encapsulating comprises the steps of: (a) providing a mixture comprising hydrogen and a carbon precursor; (b) establishing a plasma comprising the mixture; and (c) depositing carbon-containing species from the plasma onto the surface, thereby encapsulating the surface with single crystal diamond. In an even further aspect, the carbon precursor is a C1-C4 alkane. In a still further aspect, the C1-C4 alkane is methane.

In a further aspect, the ratio of the carbon precursor to hydrogen is in the range of about 1% to about 10%. In a still further aspect, the ratio of the carbon precursor to hydrogen is in the range of about 1% to about 9%. In a yet further aspect, the ratio of the carbon precursor to hydrogen is in the range of about 1% to about 8%. In an even further aspect, the ratio of the carbon precursor to hydrogen is in the range of about 1% to about 7%. In a still further aspect, the ratio of the carbon precursor to hydrogen is in the range of about 1% to about 6%. In a yet further aspect, the ratio of the carbon precursor to hydrogen is in the range of about 1% to about 5%. In an even further aspect, the ratio of the carbon precursor to hydrogen is in the range of about 1% to about 4%. In a still further aspect, the ratio of the carbon precursor to hydrogen is in the range of about 1% to about 3%. In a yet further aspect, the ratio of the carbon precursor to hydrogen is in the range of about 1% to about 2%.

In a further aspect, the ratio of the carbon precursor to hydrogen is in the range of about 2% to about 10%. In a still further aspect, the ratio of the carbon precursor to hydrogen is in the range of about 3% to about 10%. In a yet further aspect, the ratio of the carbon precursor to hydrogen is in the range of about 4% to about 10%. In an even further aspect, the ratio of the carbon precursor to hydrogen is in the range of about 5% to about 10%. In a still further aspect, the ratio of the carbon precursor to hydrogen is in the range of about 6% to about 10%. In a yet further aspect, the ratio of the carbon precursor to hydrogen is in the range of about 7% to about 10%. In an even further aspect, the ratio of the carbon precursor to hydrogen is in the range of about 8% to about 10%. In a still further aspect, the ratio of the carbon precursor to hydrogen is in the range of about 9% to about 10%.

In a further aspect, the ratio of the carbon precursor to hydrogen is in the range of about 1%, about 2%, about 3%, about 4%, about 5%, about 6%, about 7%, about 8%, about 9%, or about 10%.

In a further aspect, encapsulating comprises heating the surface. In a yet further aspect, encapsulating comprises heating the surface at a temperature of from about 800° C. to about 1300° C. In an even further aspect, encapsulating comprises heating the surface at a temperature of from about 900° C. to about 1300° C. In a still further aspect, encapsulating comprises heating the surface at a temperature of from about 1000° C. to about 1300° C. In a yet further aspect, encapsulating comprises heating the surface at a temperature of from about 1100° C. to about 1300° C. In an even further aspect, encapsulating comprises heating the surface at a temperature of from about 1200° C. to about 1300° C.

In a further aspect, encapsulating comprises heating the surface at a temperature of from about 800° C. to about 1200° C. In a still further aspect, encapsulating comprises heating the surface at a temperature of from about 800° C. to about 1100° C. In a yet further aspect, encapsulating comprises heating the surface at a temperature of from about 800° C. to about 1000° C. In an even further aspect, encapsulating comprises heating the surface at a temperature of from about 800° C. to about 900° C.

In a further aspect, encapsulating comprises heating the surface at a temperature of about 800° C., about 850° C., about 900° C., about 950° C., about 1000° C., about 1050° C., about 1100° C., about 1150° C., about 1200° C., about 1250° C., or about 1300° C.

In various aspects, the present invention relates to methods for creating a metal pattern on a surface of a diamond, the method comprising: (a) providing a diamond substrate having a surface; (b) applying a uniform polymer photoresist coating onto the surface; (c) exposing the substrate to light, wherein the light makes the exposed photoresist insoluble in a developing solution; (d) immersing the substrate in a developing solution and creating a pattern on the polymer resist coating, thereby exposing a portion of the surface; (e) depositing a uniform metal layer onto the portion of the surface; and (f) stripping the polymer resist coating; thereby creating the metal pattern on the surface of the diamond.

In a further aspect, the substrate is a single crystal. In a still further aspect, the single crystal is about one-third carat.

In a further aspect, applying comprises a spin coater.

In a further aspect, the spin coater has an angular velocity of from about 1000 rpm to about 12000 rpm. In a yet further aspect, the spin coater has an angular velocity of from about 1000 rpm to about 11000 rpm. In an even further aspect, the spin coater has an angular velocity of from about 1000 rpm to about 10000 rpm. In a still further aspect, the spin coater has an angular velocity of from about 1000 rpm to about 9000 rpm. In a yet further aspect, the spin coater has an angular velocity of from about 1000 rpm to about 8000 rpm. In a still further aspect, the spin coater has an angular velocity of from about 1000 rpm to about 7000 rpm. In a still further aspect, the spin coater has an angular velocity of from about 1000 rpm to about 6000 rpm. In a still further aspect, the spin coater has an angular velocity of from about 1000 rpm to about 5000 rpm. In a still further aspect, the spin coater has an angular velocity of from about 1000 rpm to about 4000 rpm. In a still further aspect, the spin coater has an angular velocity of from about 1000 rpm to about 3000 rpm. In a still further aspect, the spin coater has an angular velocity of from about 1000 rpm to about 2000 rpm.

In a further aspect, the spin coater has an angular velocity of from about 2000 rpm to about 12000 rpm. In a yet further aspect, the spin coater has an angular velocity of from about 3000 rpm to about 12000 rpm. In an even further aspect, the spin coater has an angular velocity of from about 4000 rpm to about 12000 rpm. In a still further aspect, the spin coater has an angular velocity of from about 5000 rpm to about 12000 rpm. In a yet further aspect, the spin coater has an angular velocity of from about 6000 rpm to about 12000 rpm. In a still further aspect, the spin coater has an angular velocity of from about 7000 rpm to about 12000 rpm. In a still further aspect, the spin coater has an angular velocity of from about 8000 rpm to about 12000 rpm. In a still further aspect, the spin coater has an angular velocity of from about 9000 rpm to about 12000 rpm. In a still further aspect, the spin coater has an angular velocity of from about 9000 rpm to about 12000 rpm. In a still further aspect, the spin coater has an angular velocity of from about 10000 rpm to about 12000 rpm. In a still further aspect, the spin coater has an angular velocity of from about 11000 rpm to about 12000 rpm.

In a further aspect, the spin coater has an angular velocity of about 1000 rpm, about 1500 rpm, about 2000 rpm, about 2500 rpm, about 3000 rpm, about 3500 rpm, about 4000 rpm, about 4500 rpm, about 5000 rpm, about 5500 rpm, about 6000 rpm, about 6500 rpm, about 7000 rpm, about 7500 rpm, about 8000 rpm, about 8500 rpm, about 9000 rpm, about 9500 rpm, about 10000 rpm, about 10500 rpm, about 11000 rpm, about 11500 rpm, or about 12000 rpm.

In a further aspect, the polymer photoresist coating comprises compounds such as such as 1-methoxy 2-propanol acetate or gamma butyrolactone, or combinations thereof. In a still further aspect, the polymer photoresist coating is a positive tone resist. In a yet further aspect, the polymer photoresist coating is a negative tone resist.

In a further aspect, exposing the photoresist to specific wavelengths of electromagnetic radiation comprises maskless lithography. In a still further aspect, photoresist exposing to these specific wavelengths of electromagnetic radiation comprises a digital micro mirror device. In a yet further aspect, the wavelength of the exposure light is in the range of from about 360 nm to about 450 nm. In an even further aspect, the wavelength of the exposure light is in the range of from about 436 nm. In a still further aspect, the wavelength of the exposure light is in the range of from about 365 nm. These wavelengths can be generated by lasers and polychromatic light sources such as light emitting diodes and mercury arc lamps.

In a further aspect, depositing a uniform metal layer onto the portion of the surface comprises sputter deposition.

In a further aspect, the metal layer comprises tungsten, iridium, molybdenum, or osmium, or combinations thereof. In a still further aspect the metal comprises tungsten. In a yet further aspect the metal comprises iridium. In an even further aspect the metal comprises molybdenum. In a still further aspect the metal comprises osmium.

In a further aspect, the metal layer has a thickness from about 0.1 microns to about 2 microns. In a still further aspect, the metal layer has a thickness from about 0.2 microns to about 2 microns. In a yet further aspect, the metal layer has a thickness from about 0.3 microns to about 2 microns. In an even further aspect, the metal layer has a thickness from about 0.4 microns to about 2 microns. In a still further aspect, the metal layer has a thickness from about 0.5 microns to about 2 microns. In a yet further aspect, the metal layer has a thickness from about 0.6 microns to about 2 microns. In an even further aspect, the metal layer has a thickness from about 0.7 microns to about 2 microns. In a still further aspect, the metal layer has a thickness from about 0.8 microns to about 2 microns. In a yet further aspect, the metal layer has a thickness from about 0.9 microns to about 2 microns. In an even further aspect, the metal layer has a thickness from about 1 micron to about 2 microns.

In a further aspect, the metal layer has a thickness from about 0.1 microns to about 1 micron. In a yet further aspect, the metal layer has a thickness from about 0.1 microns to about 0.9 microns. In an even further aspect, the metal layer has a thickness from about 0.1 microns to about 0.8 microns. In a still further aspect, the metal layer has a thickness from about 0.1 microns to about 0.7 microns. In a yet further aspect, the metal layer has a thickness from about 0.1 microns to about 0.6 microns. In an even further aspect, the metal layer has a thickness from about 0.1 microns to about 0.5 microns. In a still further aspect, the metal layer has a thickness from about 0.1 microns to about 0.4 microns. In a still further aspect, the metal layer has a thickness from about 0.1 microns to about 0.45 microns. In a yet further aspect, the metal layer has a thickness from about 0.1 microns to about 0.4 microns.

In a further aspect, the metal layer has a thickness from about 0.15 microns to about 1 micron. In a yet further aspect, the metal layer has a thickness from about 0.15 microns to about 0.9 microns. In an even further aspect, the metal layer has a thickness from about 0.15 microns to about 0.8 microns. In a still further aspect, the metal layer has a thickness from about 0.15 microns to about 0.7 microns. In a yet further aspect, the metal layer has a thickness from about 0.15 microns to about 0.6 microns. In an even further aspect, the metal layer has a thickness from about 0.15 microns to about 0.5 microns. In a still further aspect, the metal layer has a thickness from about 0.15 microns to about 0.45 microns. In a yet further aspect, the metal layer has a thickness from about 0.15 microns to about 0.4 microns.

In a further aspect, the metal layer has a thickness from about 0.2 microns to about 1 micron. In a yet further aspect, the metal layer has a thickness from about 0.2 microns to about 0.9 microns. In an even further aspect, the metal layer has a thickness from about 0.2 microns to about 0.8 microns. In a still further aspect, the metal layer has a thickness from about 0.2 microns to about 0.7 microns. In a yet further aspect, the metal layer has a thickness from about 0.2 microns to about 0.6 microns. In an even further aspect, the metal layer has a thickness from about 0.2 microns to about 0.5 microns. In a still further aspect, the metal layer has a thickness from about 0.2 microns to about 0.45 microns. In a yet further aspect, the metal layer has a thickness from about 0.2 microns to about 0.4 microns.

In a further aspect, the metal layer has a thickness from about 0.25 microns to about 1 micron. In a yet further aspect, the metal layer has a thickness from about 0.25 microns to about 0.9 microns. In an even further aspect, the metal layer has a thickness from about 0.25 microns to about 0.8 microns. In a still further aspect, the metal layer has a thickness from about 0.25 microns to about 0.7 microns. In a yet further aspect, the metal layer has a thickness from about 0.25 microns to about 0.6 microns. In an even further aspect, the metal layer has a thickness from about 0.25 microns to about 0.5 microns. In a still further aspect, the metal layer has a thickness from about 0.25 microns to about 0.45 microns. In a yet further aspect, the metal layer has a thickness from about 0.25 microns to about 0.4 microns.

In a further aspect, stripping the photoresist comprises exposing the surface to a solvent.

In a further aspect, the method further comprises the step of encapsulating the surface with single crystal diamond. In a still further aspect, encapsulating comprises microwave plasma chemical vapor deposition. In a yet further aspect, encapsulating comprises the steps of: (a) providing a mixture comprising hydrogen and a carbon precursor; (b) establishing a plasma comprising the mixture; and (c) depositing carbon-containing species from the plasma onto the surface, thereby encapsulating the surface with single crystal diamond. In an even further aspect, the carbon precursor is a C1-C4 alkane. In a still further aspect, the C1-C4 alkane is methane.

In a further aspect, the ratio of the carbon precursor to hydrogen is in the range of about 1% to about 10%. In a still further aspect, the ratio of the carbon precursor to hydrogen is in the range of about 1% to about 9%. In a yet further aspect, the ratio of the carbon precursor to hydrogen is in the range of about 1% to about 8%. In an even further aspect, the ratio of the carbon precursor to hydrogen is in the range of about 1% to about 7%. In a still further aspect, the ratio of the carbon precursor to hydrogen is in the range of about 1% to about 6%. In a yet further aspect, the ratio of the carbon precursor to hydrogen is in the range of about 1% to about 5%. In an even further aspect, the ratio of the carbon precursor to hydrogen is in the range of about 1% to about 4%. In a still further aspect, the ratio of the carbon precursor to hydrogen is in the range of about 1% to about 3%. In a yet further aspect, the ratio of the carbon precursor to hydrogen is in the range of about 1% to about 2%.

In a further aspect, the ratio of the carbon precursor to hydrogen is in the range of about 2% to about 10%. In a still further aspect, the ratio of the carbon precursor to hydrogen is in the range of about 3% to about 10%. In a yet further aspect, the ratio of the carbon precursor to hydrogen is in the range of about 4% to about 10%. In an even further aspect, the ratio of the carbon precursor to hydrogen is in the range of about 5% to about 10%. In a still further aspect, the ratio of the carbon precursor to hydrogen is in the range of about 6% to about 10%. In a yet further aspect, the ratio of the carbon precursor to hydrogen is in the range of about 7% to about 10%. In an even further aspect, the ratio of the carbon precursor to hydrogen is in the range of about 8% to about 10%. In a still further aspect, the ratio of the carbon precursor to hydrogen is in the range of about 9% to about 10%.

In a further aspect, the ratio of the carbon precursor to hydrogen is in the range of about 1%, about 2%, about 3%, about 4%, about 5%, about 6%, about 7%, about 8%, about 9%, or about 10%.

In a further aspect, encapsulating comprises heating the surface. In a yet further aspect, encapsulating comprises heating the surface at a temperature of from about 800° C. to about 1300° C. In an even further aspect, encapsulating comprises heating the surface at a temperature of from about 900° C. to about 1300° C. In a still further aspect, encapsulating comprises heating the surface at a temperature of from about 1000° C. to about 1300° C. In a yet further aspect, encapsulating comprises heating the surface at a temperature of from about 1100° C. to about 1300° C. In an even further aspect, encapsulating comprises heating the surface at a temperature of from about 1200° C. to about 1300° C.

In a further aspect, encapsulating comprises heating the surface at a temperature of from about 800° C. to about 1200° C. In a still further aspect, encapsulating comprises heating the surface at a temperature of from about 800° C. to about 1100° C. In a yet further aspect, encapsulating comprises heating the surface at a temperature of from about 800° C. to about 1000° C. In an even further aspect, encapsulating comprises heating the surface at a temperature of from about 800° C. to about 900° C.

In a further aspect, encapsulating comprises heating the surface at a temperature of about 800° C., about 850° C., about 900° C., about 950° C., about 1000° C., about 1050° C., about 1100° C., about 1150° C., about 1200° C., about 1250° C., or about 1300° C.

In various aspects, the present invention relates to a sensor prepared by the disclosed methods.

### E. Examples

The following preparations and examples are given to enable those skilled in the art to more clearly understand and to practice the present disclosure. They should not be considered as limiting the scope of the disclosure, but merely as being illustrative and representative.

1. General Experimental Methods

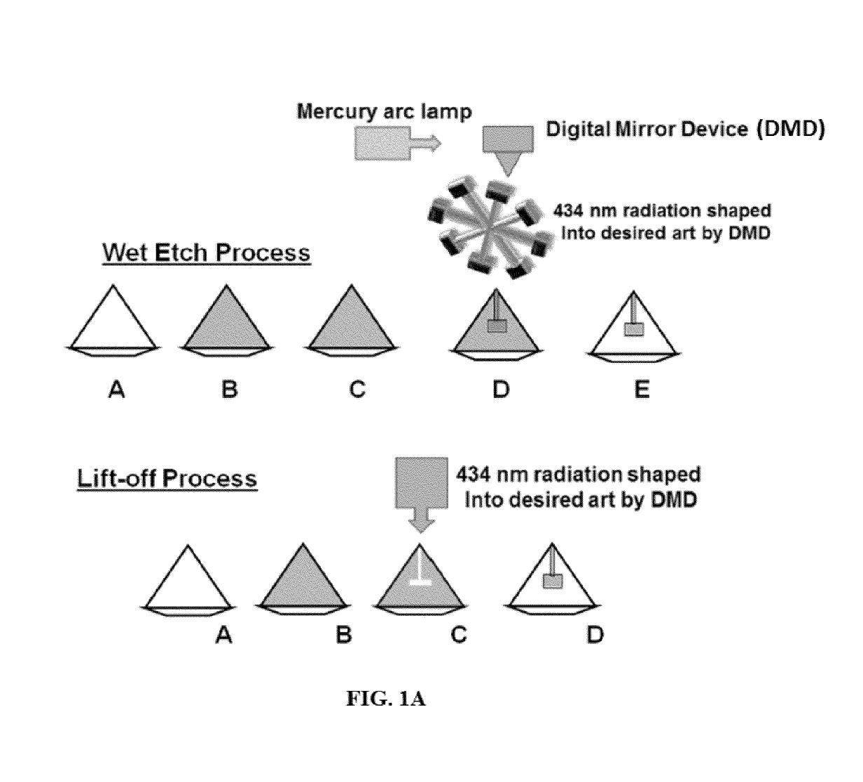

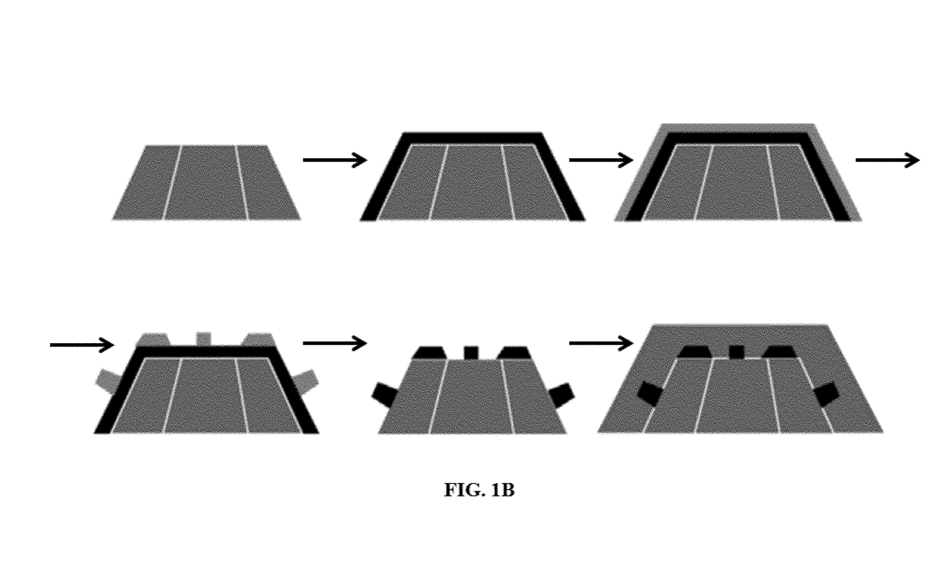

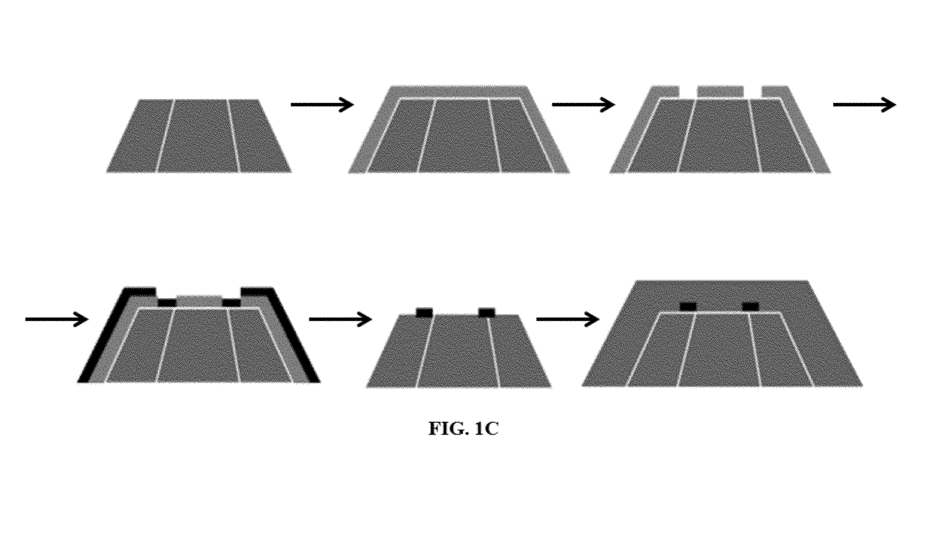

Type-Ia and Type-IIa gem quality diamonds are utilized to fabricate the designer diamond anvils. High resolution and highly customizable circuit patterns have been imprinted onto single crystal diamond (SCD) substrate anvil surfaces prior to being entirely encapsulated in SCD utilizing the following instrumentation: DC-sputter deposition, maskless lithography and microwave plasma chemical vapor deposition (MPCVD). The DC-sputter deposition system is AJA International Inc.'s (Scituate, Mass., USA) Orion sputtering system with a sputter down configuration. The maskless lithography system is SF-100 Xcel system from Intelligent Micro Patterning LLC (St. Petersburg, Fla., USA). The maskless system allows patterns to be drawn on samples with extreme topography such as diamond anvils which have angles between surfaces ranging from 7° to 45°. This is very important because electrical probes need to be extended down onto facets of diamond anvils as shown in FIG. 1. The MPCVD system is a custom built system at the University of Alabama at Birmingham. The anvil geometries utilized consist of original culet sizes ranging from 10 to 600 microns, with bevel angles (angle between the culet and facet) ranging from 7° to 50°.

2. Lithographic Process (Method 1)

The top row (TR) of graphics in FIG. 1A outline the steps of obtaining encapsulated metallic circuits on diamond anvils with the use of positive (or negative) tone resist and wet etching. In this process, the bare diamond anvil substrate (TR-A) has been etched in a gentle RF-Plasma in the sputter deposition chamber prior to sputter coating. Even before loading the diamond substrate in sputtering chamber, it was cleaned by boiling it in sulfuric acid. During the sputtering process, an RF bias has been maintained to ensure good quality metal film is deposited on the substrates. The substrate then has a uniform tungsten metal layer sputter deposited onto its surface so that the entire substrate is coated with a metallic layer (TR-B). The thickness of the metallic coating is in the range of 0.1-2 microns. After the metal has been sputter coated, photoresist (both positive tone and negative tone resists have been utilized to achieve the final result) is applied to the diamond using a spin coater with angular velocity ranging from 1000 to 12000 rotations per minute (rpm). The angular velocity is varied according to the anvil geometry in order to apply a uniform resist coating (TR-C). The resist has been processed according to manufacturer's recommendation by baking it at suitable temperature. The maskless photolithography instrument is then implemented to expose the substrate in very specific regions with visible light in the 360-450 nm range in a very high resolution pattern (micron scale resolution is achieved) via the digital micro mirror device (DMD) contained as an internal component of the maskless lithographic instrument (TR-D). Depending on the tone of the resist (positive resist becomes soluble when exposed to radiation, whereas negative resist becomes insoluble), the artwork loaded into the lithographic system software is designed specifically to meet the final circuit dimension specifications. The exposed resist is then placed in a developer solution and a pattern is rendered in the resist layer. The resist that remains is essentially a protective layer for the underlying tungsten film during the next phase of wet etching the substrate in a weakly acidic tungsten etchant. Once the etchant has completely dissolved the excess tungsten in the base layer, the substrate is removed from the solution and the photoresist layer is dissolved in a solvent. The result is a diamond anvil with a metallic pattern drawn on it (TR-E). The diamond anvil is then transferred into a 1.2 kW MPCVD chamber and SCD is grown at temperatures ranging from 800 to 1300° C. with a CH₄/H₂ ratio of 1%-10%. This results in the growth of CVD diamond with a thickness of 10-70 microns. The anvil is then polished until electrical contacts on the culet surface are exposed and the diagnostic contact pads on the facets are all exposed, facilitating the connection of external laboratory equipment.

3. Lithographic Process (Method 2)

The bottom row (BR) of FIG. 1A outlines the lift off process. The lift off process is essentially the reverse process of the wet etch procedure previously described. In the lift off process the same instrumentation, materials, and process parameters outlined in the wet-etch method are used to perform the fabrication process. However, in this method resist coating and all lithographic process steps occur on the bare SCD substrate prior to sputter deposition (BR-A,B). As a result, once the lithographic process is completed the diamond surface regions in which metal will be deposited to render the final circuit pattern are exposed to incident tungsten atoms (BR-C). During sputter deposition tungsten particles coat these regions and adhere to the diamond substrate surface. After sputter deposition, the resist layer is stripped from the diamond anvil, and the excess tungsten deposited on top of the resist layer will be removed and only the final circuit pattern remains (BR-D). Resolution enhancement has been achieved by depositing an interstitial under layer of resist prior to applying an imaging resist layer. In this bi-layer method the interstitial layer (base layer of resist deposited directly onto the diamond) has a slightly higher dissolution rate than the imaging resist that is deposited on top of it, this results in an “overhang” effect during the development phase which leads to improved resolution as sputter deposited material is less likely to delaminate from the diamond surface due to attachment of tungsten to the resist coating during the resist stripping phase. Once sputter deposition and resist stripping is complete, the anvil undergoes the same steps as in the encapsulating MPCVD and polishing phase described in Method 1.

4. Fabrication of a Designer Diamond Anvil

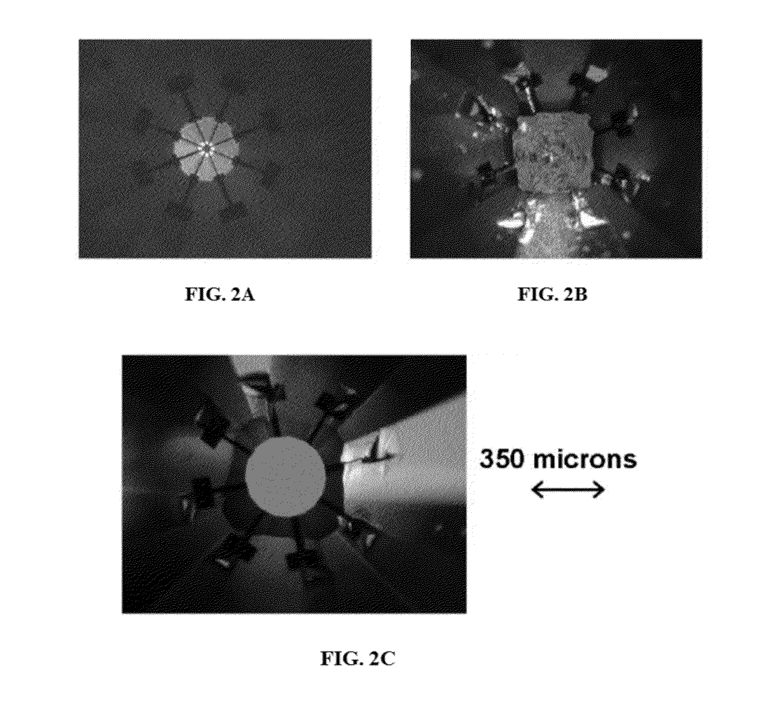

A diamond anvil with a central flat size of 70 microns in diameter, beveled at 7.5 degrees to a culet size of 350 microns in diameter, has been chosen as a base substrate for the fabrication of a designer diamond anvil. A tungsten film of 0.5 microns thick has been sputter deposited onto this diamond anvil. This diamond was then coated with Shipley 1827 positive photoresist. Utilizing an eight electrical probe design graphic file as an input for the maskless lithography system, photoresist was removed from unwanted areas. The first step in the fabrication of this designer diamond was completed after developing the photoresist, and wet etching step to remove tungsten from unwanted areas. FIG. 2A shows the resulting 8 probe pattern made of tungsten metal on the diamond anvil substrate. The width of metallic probes is 10 microns and their thickness is 0.5 microns. FIG. 2B shows the CVD diamond grown on top the eight probe pattern to encapsulate it. The fabrication of the designer diamond anvil was completed by polishing the CVD diamond layer and exposing the probes in the sample region. FIG. 2C shows a fully finished designer diamond anvil with eight electrical probes. The final culet size of this designer diamond anvil after polishing is 370 microns. The diameter of the circle of probes that have been exposed is 85 microns. These dimensions allow for researchers to include high volume of material in the high pressure research experiments. Designer diamond anvils with this geometry have been utilized in studying the electrical and magnetic properties of materials such as rare earth elements gadolinium, dysprosium (Samudrala et al. (2014) Structural and magnetic phase transitions in gadolinium under high pressures and low temperatures. High Press. Res. 34: 385-391; Samudrala et al. (2014) Magnetic ordering temperatures in rare earth metal dysprosium under ultrahigh pressures. High Press. Res. 34: 266-272).

5. Evaluation of Electrical Measurements During Superconducting Transition in Rare Earth Doped Iron-Based Compounds

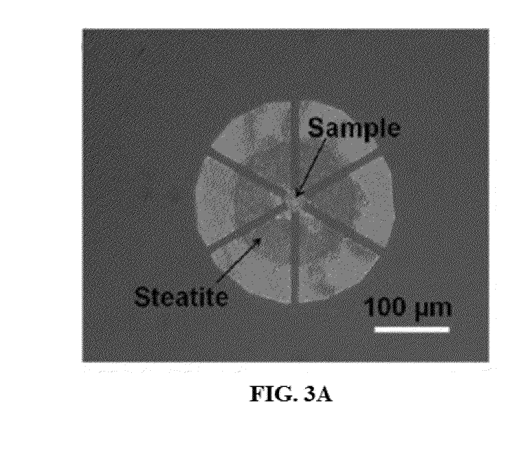

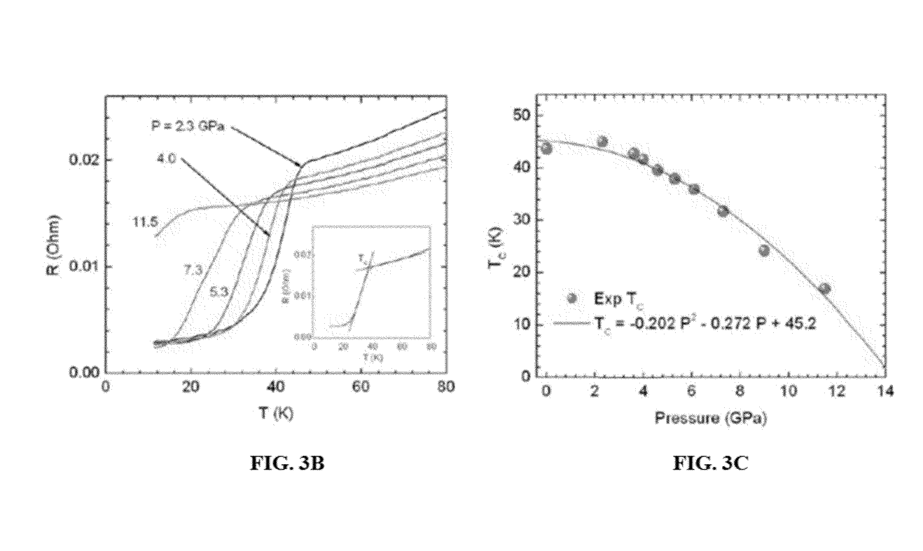

FIG. 3A shows the iron-based superconducting sample in a diamond anvil cell sample chamber assembly. The sample chamber in a stainless steel gasket is 120 microns in diameter and has an initial thickness of 70 microns and contains Ca_{0.9}Pr_{0.1}Fe₂As₂ sample along with a ruby pressure marker surrounded by an electrically insulating pressure medium steatite. The pressure was continuously monitored utilizing the spectral location of Ruby R₁ fluorescence emission at high pressures and low temperatures (Uhoya et al. (2014) High pressure effects on the superconductivity in rare-earth-doped CaFe₂As₂. High Press. Res. 34: 49-58). FIG. 3B shows the four probe electrical resistance as a function of temperature at various pressures. The onset temperature of superconductivity (T_{c}) is marked by a sharp downturn in electrical resistance and the insert in FIG. 3B illustrates this methodology for the determination of T_{c}. FIG. 3C shows a plot of T_{c} as a function of pressure and illustrates a gradual decrease of T_{c} with increasing pressure and can be fitted to the following quadratic equation:

T_{c}(in Kelvin)=45.2−0.272P−0.202P² (P is in GPa units) (1)

There is a need for simultaneous measurements of electrical properties (or T_{c}) and crystal structures on the same sample to correlate observed superconducting behavior and the crystalline phases at a given temperature and pressure. Such simultaneous measurements of superconductivity and crystal structures at high-pressure and low-temperatures are possible with the designer diamonds fabricated in this study.

6. Maskless Lithography for Fabrication of Diamond-Based Sensors

The versatility of the maskless lithography system allows fabrication of a variety of other diamond based sensors. One sensor that is currently under development is a thermocouple that can function in any extreme environment. Thin-film thermocouples have been fabricated in earlier studies on substrates such as ceramics and superalloys (Martin and Holanda. Applications of Thin Film Thermocouples for Surface Temperature Measurement. Available online: http://www.grc.nasa.gov/WWW/sensors/PhySen/docs/TM-106714.pdf (accessed on 10 Jan. 2015)). These materials have their limitations as thermocouple metals exposed to extreme environments will undergo oxidations and will suffer mechanical damage compromising their integrity. Such hazards can be avoided by sputter deposition of thermocouples on diamond substrates and encapsulating them within a single crystalline CVD diamond layer. The high thermal conductivity and chemical and radiation inertness of diamond make it an ideal candidate as a base material for building thermocouples. By utilizing sputtering, maskless lithography, thermocouple alloys can be sputter deposited on diamond substrates. Patterns made of thermocouple alloys with features down to 5 microns in width and 0.5 microns thickness can be fabricated on diamond substrates utilizing the methods described herein. These alloys can be encapsulated under CVD grown diamond and can be exposed in strategic locations to make contact with laboratory equipment.

7. High Pressure Studies Using Two-Stage Diamond Micro-Anvils

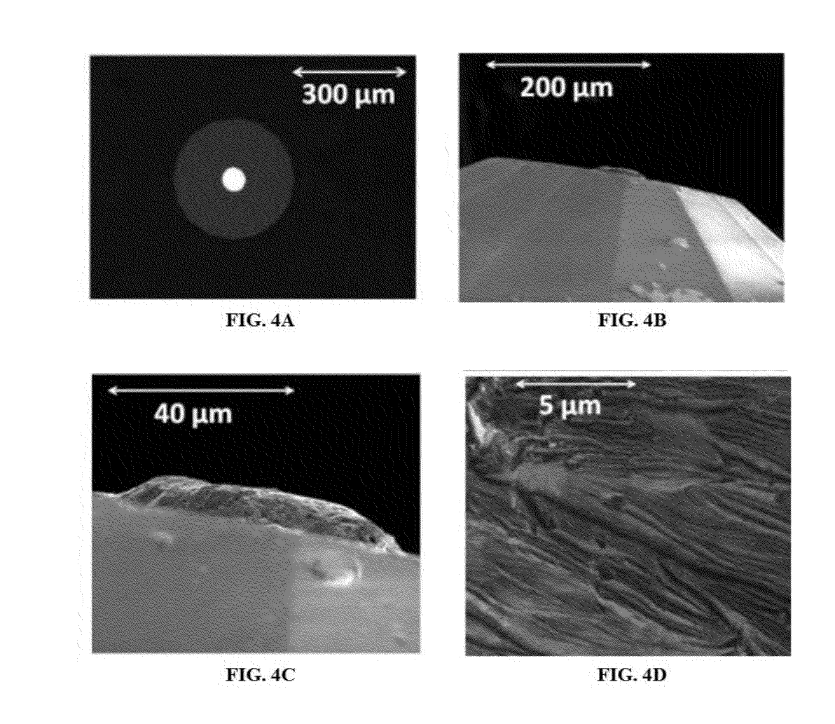

Type Ia ⅓ carat diamond anvils with 300 μm culet size were selected for this experiment. A thin layer of tungsten (˜500 nm thick) was then sputter deposited onto the diamond anvil using AJA International Inc's Orion sputtering system. The substrates were first cleaned by boiling them in sulfuric acid, and were subsequently cleaned by an RF etch prior to sputter deposition to prepare the surface for the following DC sputter deposition. An RF bias was maintained throughout the sputtering process to ensure that good-quality tungsten films were deposited. A uniform layer of photoresist was then applied to the tungsten-coated diamond. Utilizing an SF-100 maskless lithography system from Intelligent Micro Patterning LLC, the photoresist was removed from a circular area of 50 μm in diameter at the center of the culet. The diamond was then placed in a commercially available tungsten etchant. This creates a circular hole of 50 μm in diameter at the exact center of the culet in the tungsten film (as shown in FIG. 4A). Microwave plasma CVD of diamond was then carried out on this masked anvil using high methane gas chemistry (9% CH4/H2). As shown in FIGS. 4B-4D, the disclosed methods can provide a “second-stage” anvil on the original diamond anvil.

X-ray diffraction was then performed on sample pressurized with the two-stage micro-anvils at the HPCAT 16 ID-B beamline at the Advanced Photon Source (APS) at Argonne National Laboratories in Chicago, Ill. A 30.494 keV beam of X-rays was collimated to a spot size with full-width at half-maximum of 5×7 μm and scanned across the sample area, while spectra were collected at each point. The scanned points were centered at the highest point of X-ray transmission—determined by moving an X-ray-sensitive diode behind the sample in the x and y directions to identify the point of greatest transmission before the scan—and covered a 60 μm×60 μm area with points every 10 μm (49 points in total for each scan, with one point at the center). A Diacell iGM Controller was used to control the gas membrane pressure.

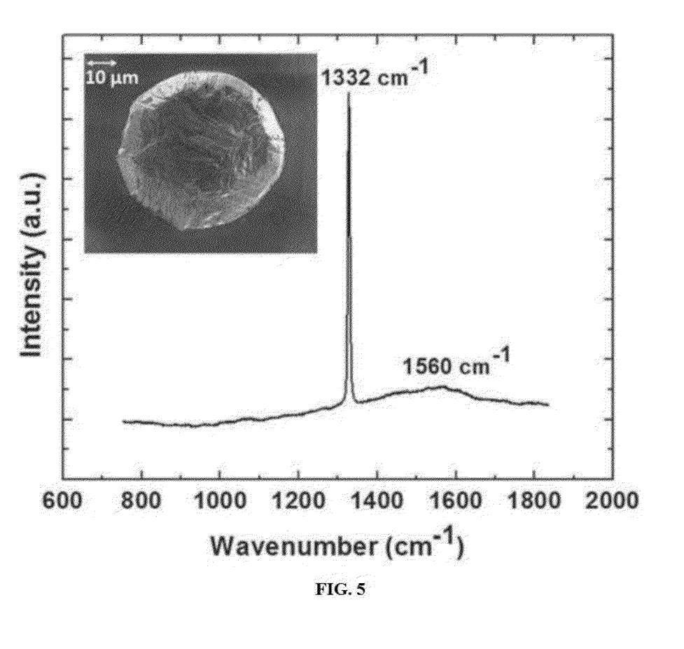

The steps involved in the fabrication of two-stage diamond micro-anvils by combining the maskless lithography process and CVD of diamond are summarized in FIGS. 4A-4D. The second stage shows surface growth steps typical of homoepitaxially grown diamond as indicated in the high resolution scanning electron microscope image shown in FIG. 4D. The homoepitaxial nature of grown diamond is further confirmed by Raman spectroscopy performed on the second-stage anvil (FIG. 5). The Raman spectrum shows a high-purity diamond phase with a dominant peak at 1332 cm-1 and with a very weak peak attributed to non-diamond carbon at 1560 cm-1 clearly labeled in FIG. 5. There is not any apparent stress-induced shift of the diamond Raman mode at 1332 cm⁻¹ from the second-stage anvil thereby confirming a high-quality homoepitaxial diamond growth. NCD with a signature peak at 1130-1170 cm⁻¹ was not observed in the Raman spectrum of second-stage anvil. The second-stage anvil is thus a homoepitaxial continuation of the first-stage diamond anvil with a minimal contamination of non-diamond carbon.

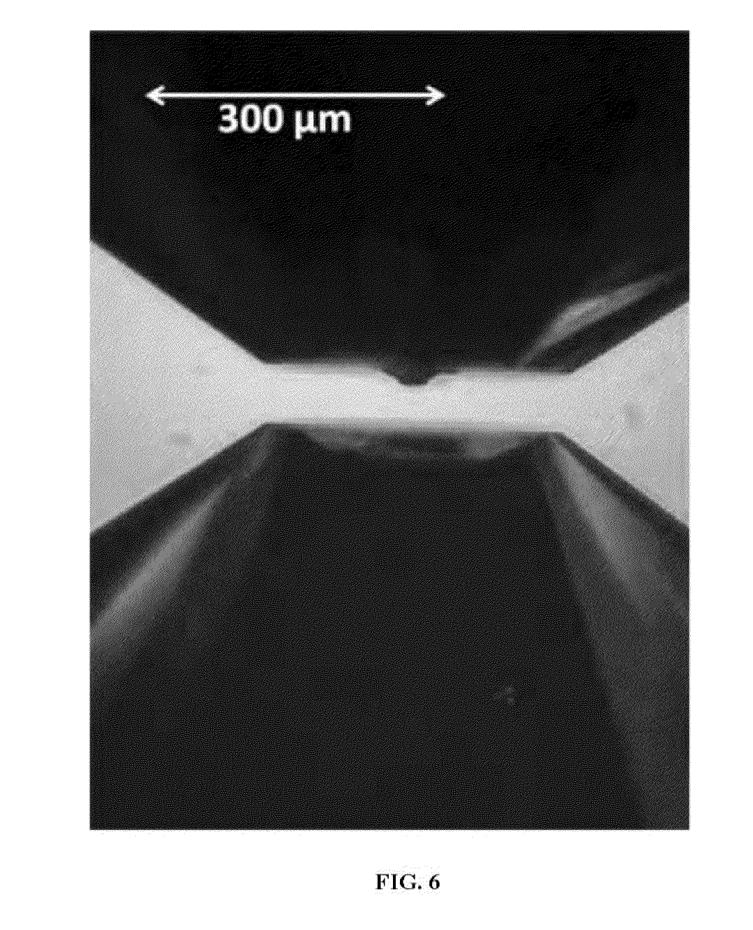

The two-stage diamond micro-anvil (with a culet size of 300 μm in diameter and a second stage with 50 μm in diameter) was matched with a standard 300 μm culet size flat diamond in an opposed anvil configuration (FIG. 6). A spring steel gasket with an initial thickness of 250 μm was pre-indented to a thickness of 50 μm using the two-stage anvil. It is to be noted that there was no visible damage to the second-stage anvil after gasket indentation and the standard sample preparation techniques used in diamond anvil cell experiments can be readily adapted in experiments with these anvils. A hole of 80 μm in diameter was drilled in the spring steel gasket and filled with a polycrystalline lutetium sample (99.9% stated purity foil from Alfa Aesar) and a 2 μm thick copper foil was placed on top for pressure calibration purposes. The high pressure angle-dispersive X-ray diffraction studies on double-stage micro-diamond anvils were carried out at the APS, Argonne National Laboratory beamline 16-ID-B.

The resulting diffraction patterns of the x-y scans were collected using a Pilatus 1 M (Broennimann C, et al. J Synchrotron Radiat. (2006) 13:120-130.) detector, a rapid collection system that allows for collection times as short as 7 ms in duration—a 100 million-fold improvement over the first high pressure XRD experiments (Bassett W A. High Pressure Res. (2009) 29(2):163-186). However, to achieve optimal statistics, the sample was left to collect for one whole second at each point in the scan, but as the motor controls and communication hardware only allowed for each individual x, y data points to be recorded every 5 s, each full scan of the second-stage anvil took approximately 5 min to complete.

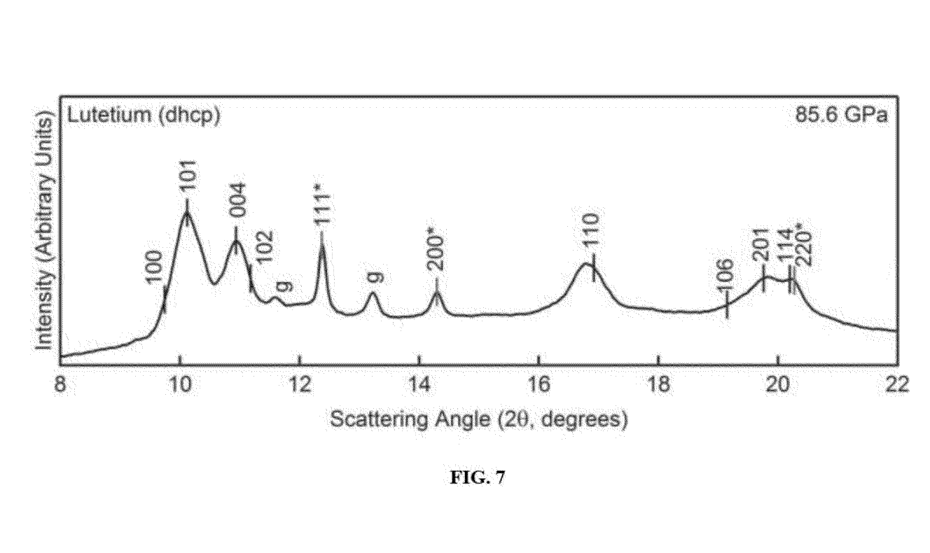

Pressures were calculated from the (111) and (200) diffraction peaks of the copper pressure marker, using the Birch-Murnaghan equation of state (Birch F. Phys Rev. (1947) 71:809):

$$P = 3 {B}_{0} {f ( 1 + 2 f )}^{5 / 2} ( 1 + {a}_{1} f + … ) , \\ f = \frac{1}{2} [ {( \frac{{V}_{0}}{V} )}^{2 / 3} - 1 ] , \\ {a}_{1} = \frac{3}{2} ( {B}_{0}^{′} - 4 ) ,$$

where B₀ is the bulk modulus of the material, B′₀ is the pressure derivative of B₀, and V₀ is the unit cell volume at ambient conditions. In the study described herein, the equation of state of copper from Velisavljevic N. and Vohra Y. K. (High Pressure Res. (2004) 24:295.) was used, with a bulk modulus B_{0,Cu}=121.6 GPa with pressure derivative B′_{0,Cu}=5.583 and an initial volume per atom of V₀=11.802 Å³. A maximum pressure of 85.6±0.5 GPa was reached at the highest membrane pressure of 95 bar and the sample was subsequently decompressed to ambient conditions. FIG. 7 shows the spectrum taken at the center of the scan area, where the highest pressure was measured. The diffraction peaks from the lutetium sample were indexed using the (101), (004), (110), (201), and (114) peaks of the double hexagonal close packed (dhcp) phase while the remaining peaks were calculated. The diffraction peaks from the face-centered cubic phase of copper are marked with an asterisk *, and hcp Fe gasket peaks are marked with “g”.

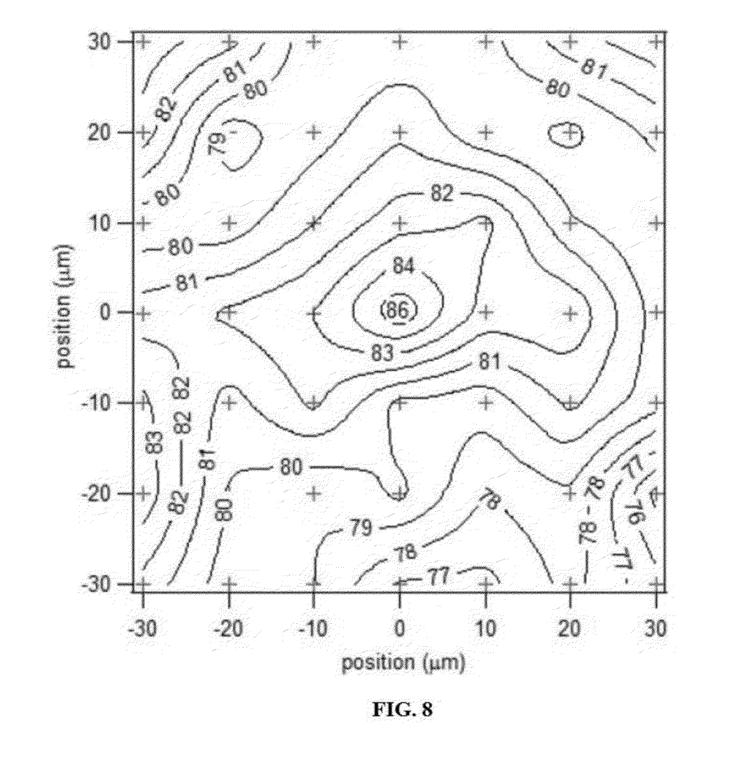

The measured lattice parameters of the dhcp phase of the lutetium sample at this pressure were a_{Lu}=2.763±0.001 Å and c_{Lu}=8.529±0.002 Å, respectively, while the lattice parameter of the copper pressure marker was measured to be aCu=3.267±0.004 Å. The existence of the high pressure dhcp phase of lutetium at 86 GPa and the sample volume is consistent with previously published work (Samudrala G. K. and Vohra Y. K. “Structural properties of lanthanides at ultra high pressures.” In: Bünzli Jean-Claude G. and Pecharsky V. K., editors. Handbook on the physics and chemistry of rare earths. Vol. 43, North Holland: Elsevier; 2013. p. 275-319). FIG. 7 also shows the calculated peak positions based on fitted lattice parameters for lutetium and copper described above indicating a good agreement with the observed spectrum. FIG. 8 shows the pressure distribution across the second stage of micro-anvil by X-ray diffraction techniques. The “+” symbols represent the experimentally measured data points in the x-y scans and the contours are mainly drawn as a guide to the eye. The highest pressure in this scan is 86 GPa and this measurement shows that the CVD diamond second stage does support pressure gradient and these gradients are driven by the local geometry of diamond and shear strength of the sample being studied. The sample was successfully decompressed from this pressure to ambient conditions to examine any signs of plastic deformation of the second-stage diamond micro-anvil.

The two-stage diamond micro-anvil was successfully recovered after decompression from 86 GPa and no visible damage or plastic deformation of the microanvil was observed. These studies indicate that these diamonds can be utilized in multiple high pressure cycles like the conventional anvils. The experiment was terminated due to limits on the membrane gas pressure and can be remedied by reducing the initial thickness of the gasket and reduction in overall diamond culet size. In various aspects, it is believed that higher pressures would likely require reducing the diameter of the second-stage micro-anvil to 10-20 μm and controlling the diamond growth parameters to optimize the mechanical properties of the second-stage micro-anvil.

In summary, the data and methods described herein provide a new technique for the fabrication of two-stage diamond microanvils for studies on materials under extreme conditions. This is accomplished by combining maskless lithography and microwave plasma CVD of diamond. A prototype two-stage diamond anvil with culet diameter of 300 μm in diameter and a second stage with diameter of 50 μm was employed in high pressure experiments on rare-earth metal lutetium to 86 GPa. The pressure enhancement due to the second-stage anvil was confirmed by the measured pressure gradient. The sample was successfully decompressed and the two-stage diamond micro-anvil was recovered without any damage to the second stage. It is believed that higher pressures in the second stage can be achieved by reducing its size and optimizing gasket geometry. In various aspects, the mechanical properties of second stage can also be tuned by changing the microcrystalline/nanocrystalline component during the diamond growth process by the CVD method.

8. Generalized Method for the Fabrication of Diamond Based Sensors for Use in Extreme Environments

The generalized method for the fabrication of diamond-based sensors for use in extreme environments comprises utilizing maskless lithography and chemical vapor deposition. The steps involved in fabricating a diamond based sensor are listed herein below. It can be appreciated by one skilled in the art that the steps listed herein can be added to and further optimized as required by the specific circumstances and requirements of the sensor being fabricated. The generalized method comprises the following steps: (1) the first step in fabricating a diamond based sensor comprises cleaning the sample, e.g., boiling the diamond substrate in sulfuric acid in the temperature range of 80-120° C., or alternatively a mixture of nitric acid and hydrochloric acid in 1:3 ratios has also been used to clean the sample; (2) the second step comprises drawing the desired pattern, such as an electronic circuit, on the diamond with a metal, wherein the drawing can be accomplished by either wet etching or a lift-off process; (3) when the desired pattern is drawn using a wet etching process, the steps comprise metal deposition, photoresist coating, exposing photoresist, photoresist developing, and chemical etching to remove metal; (4) when the desired pattern is drawn using a lift-off process, it comprises following steps—photoresist coating, exposing photoresist, developing photoresist, metal deposition, and photoresist stripping; (5) once the desired pattern has been drawn on the diamond with a metal, the diamond is then placed in a chemical vapor deposition chamber to allow a layer of diamond to grow such that the diamond layer completely encapsulates the circuit in order to protect the circuit from extreme environments during an experiment or data collection session; and (6) the diamond sensor is polished in strategic locations to expose parts of lithographically drawn circuit so that connections to other equipment could be made or the sensor can be put in direct contact with the sample being investigated.

The process of obtaining encapsulated metallic circuits on diamond anvils with the use of positive (or negative) tone resist and wet etching are described further in the following generalized method, with reference to FIG. 1A:
(1) After the diamond is cleaned by way of boiling in acid, the bare diamond anvil substrate has been etched in a RF-Plasma in the sputter deposition chamber prior to sputter coating. An RF-power of 35 Watts can be used for this process which generates a bias of −300 volts on the sample. Depending on sample size, RF power in the range of 15-40 W can also be used.
(2) During the sputtering process, an RF bias (5 watts to 10 Watts) has been maintained to ensure we deposit good quality metal film on our substrates.
(3) A typical sputter deposition run lasts 20-35 minutes. The entire substrate is coated with a metallic layer (FIG. 1A, top row, image B). The thickness of the metallic coating is in the range of 0.1-2 microns.
(4) After the metal has been sputter coated, photoresist (both positive tone and negative tone resists have been utilized to achieve the final result) is applied to the diamond using a spin coater with angular velocity ranging from 1000 to 12000 rotations per minute (rpm). The angular velocity is varied according to the anvil geometry in order to apply a uniform resist coating (FIG. 1A, top row, image C).
(5) The resist has been processed according to manufacturer's recommendation by baking it at suitable temperature.
(6) The maskless photolithography instrument is then implemented to expose the substrate in very specific regions with light in the 360-450 nm range in a very high resolution pattern (micron scale resolution is achieved) via the digital micro mirror device (DMD) contained as an internal component of the maskless lithographic instrument (FIG. 1A, top row, image D). Depending on the tone of the resist (positive resist becomes soluble when exposed to radiation, whereas negative resist becomes insoluble), the artwork loaded into the lithographic system software is designed specifically to meet the final circuit dimension specifications.
(7) The exposed resist is then placed in a developer solution and a pattern is rendered in the resist layer. The resist that remains is essentially a protective layer for the underlying tungsten film during the next phase of wet etching.
(8) The substrate is immersed in a weakly acidic tungsten etchant. Once the etchant has completely dissolved the excess tungsten in the base layer, the substrate is removed from the solution and the photoresist layer is dissolved in a solvent. The result is a diamond anvil with a metallic pattern drawn on it (FIG. 1A, top row, image E).
(9) The diamond anvil is then transferred into a 1.2 kW MPCVD chamber and single crystal diamond (SCD) is grown at temperatures ranging from 800 to 1300° C. with a CH4/H2 ratio of 1%-10%. This results in the growth of CVD diamond with a thickness of 10-70 microns. The anvil is then polished until electrical contacts on the culet surface are exposed and the diagnostic contact pads on the facets are all exposed, facilitating the connection of external laboratory equipment.

The process of obtaining encapsulated metallic circuits on diamond anvils with the use of the lift-off process described further in the following generalized method, with reference to FIG. 1A:
(1) The lift off process is essentially the reverse process of the wet etch procedure previously described. In the lift off process the same instrumentation, materials and process parameters outlined in the wet-etch method are used to perform the fabrication process. However, in this method resist coating and all lithographic process steps occur on the bare SCD substrate prior to sputter deposition (FIG. 1A, bottom row, image A and B).
(2) As a result, once the lithographic process is completed the diamond surface regions in which metal will be deposited to render the final circuit pattern are exposed to incident tungsten atoms (FIG. 1A, bottom row, image C).
(3) During sputter deposition tungsten particles coat these regions and adhere to the diamond substrate surface.
(4) After sputter deposition, the resist layer is stripped from the diamond anvil, and the excess tungsten deposited on top of the resist layer will be removed and only the final circuit pattern remains (FIG. 1A, bottom row, image D).
(5) Resolution enhancement has been achieved by depositing an interstitial under layer of resist prior to applying an imaging resist layer. In this bi-layer method the interstitial layer (base layer of resist deposited directly onto the diamond) has a slightly higher dissolution rate than the imaging resist that is deposited on top of it, this results in an “overhang” effect during the development phase which leads to improved resolution as sputter deposited material is less likely to delaminate from the diamond surface due to attachment of tungsten to the resist coating during the resist stripping phase. Once sputter deposition and resist stripping is complete, the anvil undergoes the same steps as in the encapsulating MPCVD and polishing phase as described above.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for creating a metal pattern on a surface of a diamond, the method comprising:
(a) providing a diamond substrate having a surface;
(b) depositing a uniform metal layer onto the surface;
(c) applying a uniform polymer photoresist coating onto the metal layer;
(d) exposing the substrate to light, wherein the light makes positive tone photoresist coating soluble in a developing solution, and wherein the light makes negative tone photoresist insoluble in a developing solution;
(e) developing the photoresist coating after exposing it to light, wherein a pattern is created on the photoresist coating, thereby exposing any excess metal;
(f) dissolving the excess metal; and
(g) stripping the polymer resist coating;
thereby creating the metal pattern on the surface of the diamond.

2. The method of claim 1, wherein the substrate is a single crystal.

3. The method of claim 1, wherein the metal layer comprises tungsten, iridium, molybdenum, or osmium, or combinations thereof.

4. The method of claim 1, wherein the metal layer is from about 0.1 microns to about 2 microns in thickness.

5. The method of claim 1, wherein the polymer photoresist coating is a positive tone resist.

6. The method of claim 1, wherein the polymer photoresist coating is a negative tone resist.

7. The method of claim 1, wherein exposing the photoresist comprises maskless lithography.

8. The method of claim 1, wherein the light has a wavelength in the range of from about 360 nm to about 450 nm.

9. The method of claim 1, further comprising the step of encapsulating the metal pattern on the surface of the diamond with single crystal diamond.

10. The method of claim 9, wherein encapsulating the metal pattern on the surface of the diamond with single crystal diamond comprises microwave plasma chemical vapor deposition.

11. The method of claim 9, wherein encapsulating comprises the steps of:
(a) providing a mixture comprising hydrogen and a carbon precursor;
(b) establishing a plasma comprising the mixture; and
(c) depositing carbon-containing species from the plasma onto the surface,
thereby encapsulating the metal pattern on the surface of the diamond with single crystal diamond.

12. A sensor prepared by the method of claim 1.

13. A method for creating a metal pattern on a surface of a diamond, the method comprising:
(a) providing a diamond substrate having a surface;
(b) applying a uniform polymer photoresist coating onto the surface;
(c) exposing the substrate to light, wherein the light makes the exposed photoresist insoluble in a developing solution;
(d) immersing the substrate in a developing solution and creating a pattern on the polymer resist coating, thereby exposing a portion of the surface;
(e) depositing a uniform metal layer onto the portion of the surface; and
(f) stripping the polymer resist coating;
thereby creating the metal pattern on the surface of the diamond.

14. The method of claim 13, wherein the substrate is a single crystal.

15. The method of claim 13, wherein exposing the photoresist comprises maskless lithography.

16. The method of claim 13, wherein the metal layer comprises tungsten, iridium, molybdenum, or osmium, or combinations thereof.

17. The method of claim 13, wherein the metal layer has a thickness from about 0.1 microns to about 2 microns in thickness.

18. The method of claim 13, further comprising the step of encapsulating the surface with single crystal diamond.

19. The method of claim 18, wherein encapsulating comprises microwave plasma chemical vapor deposition.

20. The method of claim 18, wherein encapsulating comprises the steps of:
(a) providing a mixture comprising hydrogen and a carbon precursor;
(b) establishing a plasma comprising the mixture; and
(c) depositing carbon-containing species from the plasma onto the surface,
thereby encapsulating the metal pattern on the surface of the diamond with a single crystal diamond.

21. A sensor prepared by the method of claim 13.
